(19) United States
(12) Patent Application Publication
(10) Pub. No.: US 2022/0336351 A1
(43) Pub. Date: Oct. 20, 2022

(54) MULTIPLE FUNCTION BLOCKS ON A SYSTEM ON A CHIP (SOC)

(71) Applicant: QUALCOMM Incorporated, San Diego, CA (US)

(72) Inventors: John Jianhong ZHU, San Diego, CA (US); Junjing BAO, San Diego, CA (US); Giridhar NALLAPATI, San Diego, CA (US)

(21) Appl. No.: 17/234,377

(22) Filed: Apr. 19, 2021

(51) Int. Cl. H01L 23/528; H01L 23/522; H01L 25/18; H01L 21/768

(52) U.S. Cl. CPC H01L 23/5283; H01L 23/5226; H01L 25/18; H01L 21/76802; H01L 21/76877; H01L 21/7684; H01L 21/76819

(57) ABSTRACT

In an aspect, a system on a chip (SOC) includes a plurality of function blocks, including a first function block and a second function block, co-located on the SOC. The SOC includes a first metal layer, a first dielectric layer located on top of the first metal layer, and a first via located in the first dielectric layer and used in the first function block. The SOC includes a second via located in the first dielectric layer and used in the second function block and a second metal layer located on the first dielectric layer. The second metal layer comprises a first set of connections used in the first function block and a second set of connections used in the second function block. The first set of connections is different from the second set of connections. The SOC includes a second dielectric layer located on the first dielectric layer.

### BACKGROUND OF THE DISCLOSURE

### 1. Field of the Disclosure

Aspects of this disclosure relate generally to integrated circuit (IC) fabrication, and particularly to customizing criteria, such as resistance (R), capacitance (C) or the like, for individual function blocks residing on a same system on a chip (SOC).

### 2. Description of the Related Art

A SOC may include multiple function blocks, with each function block designed to perform a specific function, such as, for example, a microprocessor function, a graphics processing unit (GPU) function, a communications function (e.g., Wi-Fi, Bluetooth, and other communications), and the like. Individual function blocks and particular types of paths on the SOC may have specific criteria for resistance (R), capacitance (C), and the like. For example, a function block used as a wake-up function may be infrequently used and may be capable of functioning with a relatively high resistance connection. In contrast, a function block, such as a GPU, that frequently performs a large number of operations, may perform faster with low resistance connections that reduce heat build-up and the possibility of over-heating. However, current integrated circuit (IC) manufacturing techniques do not provide the flexibility to accommodate different criteria (e.g., R, C, or the like) for function blocks.

### SUMMARY

The following presents a simplified summary relating to one or more aspects disclosed herein. As such, the following summary should not be considered an extensive overview relating to all contemplated aspects, nor should the following summary be regarded to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In a first aspect, an apparatus comprises a system on a chip (SOC) that includes a plurality of function blocks co-located on the SOC. The SOC includes a first metal layer, a first dielectric layer located on top of the first metal layer, a first via located in the first dielectric layer that is used in a first function block of the plurality of function blocks, a second via located in the first dielectric layer that is used in a second function block of the plurality of function blocks, and a second metal layer located on the first dielectric layer. The second metal layer include a first set of connections used in the first function block and a second set of connections used in the second function block. The first set of connections may be different from the second set of connections. The SOC includes a second dielectric layer located on the first dielectric layer

In a second aspect, a method of fabricating a system on a chip (SOC) includes depositing a first metal layer on a substrate, depositing a first dielectric layer on the first metal layer, and etching a first via in the first dielectric layer. The first via is used in a first function block of a plurality of function blocks. The plurality of function blocks are co-located on the SOC. The method includes etching a second via located in the first dielectric layer used in a second function block of the plurality of function blocks and depositing a second metal layer on top of the first dielectric layer. The second metal layer includes a first set of connections used in the first function block and a second set of connections used in the second function block. The first set of connections is different from the second set of connections. The method includes removing a portion of the second metal layer and depositing a second dielectric layer on the first dielectric layer.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof. A more complete understanding of the present disclosure may be obtained by reference to the following Detailed Description when taken in conjunction with the accompanying Drawings. In the figures, the left-most digit(s) of a reference number identifies the figure in which the reference number first appears. The same reference numbers in different figures indicate similar or identical items.

FIG. 1 illustrates an exemplary system on a chip (SOC), according to various aspects of the disclosure.

FIGS. 2A, 2B, 2C, 2D, 2E, and 2F illustrate a first back end of line (BEOL) process that includes creating vias having different widths, according to aspects of the disclosure.

FIGS. 3A, 3B, 3C, 3D, 3E, 3F, and 3G illustrate a second BEOL process that includes creating vias having different depths, according to aspects of the disclosure.

FIGS. 4A, 4B, 4C, 4D, 4E, 4F, and 4G illustrate a third BEOL process that includes creating recessed vias, according to aspects of the disclosure.

FIG. 5 illustrates an example process that includes depositing a second metal layer on a first dielectric layer, according to aspects of the disclosure.

FIG. 6 illustrates an example process that includes creating one or more recessed etches, according to aspects of the disclosure.

FIG. 7 illustrates components of an integrated device in accordance with one or more aspects of the disclosure.

FIG. 8 illustrates an exemplary mobile device in accordance with one or more aspects of the disclosure.

FIG. 9 illustrates various electronic devices that may be integrated with an integrated device or a semiconductor device in accordance with one or more aspects of the disclosure.

### DETAILED DESCRIPTION

Disclosed are systems and techniques to customize criteria, such as resistance (R) and capacitance (C), for individual function blocks located on a single system on a chip (SOC). Integrated circuit (IC) fabrication has 2 main steps, (1) front end of line (FEOL) and back end of line (BEOL). During BEOL, individual devices (transistors, capacitors, resistors, and the like) are interconnected with wiring on a wafer, using a metallization layer. BEOL begins when a first layer of metal is deposited on the wafer. BEOL includes contacts, insulating layers (dielectrics), metal levels, and bonding sites for chip-to-package connections. The properties of an interconnect may include width, thickness, spacing (the distance between a first interconnect and a second interconnect on a same level), pitch (the sum of the width and spacing), and aspect ratio (AR=thickness divided by width). The width, spacing, AR, and pitch, may be constrained to minimum and maximum values because of design rules that enable the interconnect (and therefore the IC) to be fabricated using a particular technology with a reasonable yield. For example, current minimum BEOL pitch is 28 nanometers (nm).

Using a single metal, such as Copper (Cu), for interconnects may not enable the different preferences of function blocks to be accommodated. By using multiple metals during BEOL, different types of function blocks can use different metals for interconnects. For example, depending on the function being performed, some function blocks may benefit from using a metal with a low R, a low C, or the like. The systems and techniques described herein enable the use of multiple metals for interconnects. The multiple metals may, for example, include Copper (Cu), Cobalt (Co), Ruthenium (Ru), Tungsten/Wolfram (W), Molybdenum (Mo), Gold (Au), Silver (Ag), Aluminum (Al), Tin (Sn), or the like.

The systems and techniques described herein may be used to create a SOC. For example, during BEOL to create a SOC, after depositing a first dielectric layer on a first metal layer, the first metal layer may be etched to create one or more vias. A via is an opening in an insulating oxide layer to enable a conductive connection between different layers. For each function block, a second metal layer may be deposited on top of the first dielectric layer and then etched. The second metal layer may, for example, use a different metal (e.g., Co, Ru, W, Mo, or the like) than the first metal layer (e.g., Cu), and may be specific to the function block. After the second metal layer has been etched, a second dielectric layer may be deposited and chemical mechanical polishing (CMP) may be performed to complete the BEOL. To accommodate different function blocks, the metal used for the second metal layer may be specific to a particular function block. For example, the second metal layer may use a second metal for a first function block and may use a third metal for a second function block. In this example, three metal layers are used, e.g., a first metal for the first metal layer, a second metal for the second metal layer of the first function block, and a third metal for the second metal layer of the second function block. Of course, a different metal may be used for the second metal layer for additional function blocks, resulting in more than 3 metals being used.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “example” and/or “example” are used herein to mean “serving as an example, instance, or illustration.” Any aspect described herein as “example” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

As used herein, the terms “user equipment” (UE) and “base station” are not intended to be specific or otherwise limited to any particular radio access technology (RAT), unless otherwise noted. In general, a UE may be any wireless communication device (e.g., a mobile phone, router, tablet computer, laptop computer, tracking device, wearable device (e.g., smartwatch, glasses, augmented reality (AR)/virtual reality (VR) headset, etc.), vehicle (e.g., automobile, motorcycle, bicycle, etc.), Internet of Things (IoT) device, etc.) used by a user to communicate over a wireless communications network. A UE may be mobile or may (e.g., at certain times) be stationary, and may communicate with a radio access network (RAN). As used herein, the term “UE” may be referred to interchangeably as an “access terminal” or “AT,” a “client device,” a “wireless device,” a “subscriber device,” a “subscriber terminal,” a “subscriber station,” a “user terminal” or UT, a “mobile device,” a “mobile terminal,” a “mobile station,” or variations thereof. Generally, UEs can communicate with a core network via a RAN, and through the core network the UEs can be connected with external networks such as the Internet and with other UEs. Of course, other mechanisms of connecting to the core network and/or the Internet are also possible for the UEs, such as over wired access networks, wireless local area network (WLAN) networks (e.g., based on Institute of Electrical and Electronics Engineers (IEEE) 802.11, etc.) and so on.

A base station may operate according to one of several RATs in communication with UEs depending on the network in which it is deployed, and may be alternatively referred to as an access point (AP), a network node, a NodeB, an evolved NodeB (eNB), a next generation eNB (ng-eNB), a New Radio (NR) Node B (also referred to as a gNB or gNodeB), etc. A base station may be used primarily to support wireless access by UEs, including supporting data, voice, and/or signaling connections for the supported UEs. In some systems a base station may provide purely edge node signaling functions while in other systems it may provide additional control and/or network management functions. A communication link through which UEs can send RF signals to a base station is called an uplink (UL) channel (e.g., a reverse traffic channel, a reverse control channel, an access channel, etc.). A communication link through which the base station can send RF signals to UEs is called a downlink (DL) or forward link channel (e.g., a paging channel, a control channel, a broadcast channel, a forward traffic channel, etc.). As used herein the term traffic channel (TCH) can refer to either an uplink/reverse or downlink/forward traffic channel.

The term “base station” may refer to a single physical transmission-reception point (TRP) or to multiple physical TRPs that may or may not be co-located. For example, where the term “base station” refers to a single physical TRP, the physical TRP may be an antenna of the base station corresponding to a cell (or several cell sectors) of the base station. Where the term “base station” refers to multiple co-located physical TRPs, the physical TRPs may be an array of antennas (e.g., as in a multiple-input multiple-output (MIMO) system or where the base station employs beamforming) of the base station. Where the term “base station” refers to multiple non-co-located physical TRPs, the physical TRPs may be a distributed antenna system (DAS) (a network of spatially separated antennas connected to a common source via a transport medium) or a remote radio head (RRH) (a remote base station connected to a serving base station). Alternatively, the non-co-located physical TRPs may be the serving base station receiving the measurement report from the UE and a neighbor base station whose reference RF signals (or simply “reference signals”) the UE is measuring. Because a TRP is the point from which a base station transmits and receives wireless signals, as used herein, references to transmission from or reception at a base station are to be understood as referring to a particular TRP of the base station.

In some implementations that support positioning of UEs, a base station may not support wireless access by UEs (e.g., may not support data, voice, and/or signaling connections for UEs), but may instead transmit reference signals to UEs to be measured by the UEs, and/or may receive and measure signals transmitted by the UEs. Such a base station may be referred to as a positioning beacon (e.g., when transmitting signals to UEs) and/or as a location measurement unit (e.g., when receiving and measuring signals from UEs).

An “RF signal” comprises an electromagnetic wave of a given frequency that transports information through the space between a transmitter and a receiver. As used herein, a transmitter may transmit a single “RF signal” or multiple “RF signals” to a receiver. However, the receiver may receive multiple “RF signals” corresponding to each transmitted RF signal due to the propagation characteristics of RF signals through multipath channels. The same transmitted RF signal on different paths between the transmitter and receiver may be referred to as a “multipath” RF signal. As used herein, an RF signal may also be referred to as a “wireless signal,” a “radar signal,” a “radio wave,” a “waveform,” or the like, or simply a “signal” where it is clear from the context that the term “signal” refers to a wireless signal or an RF signal.

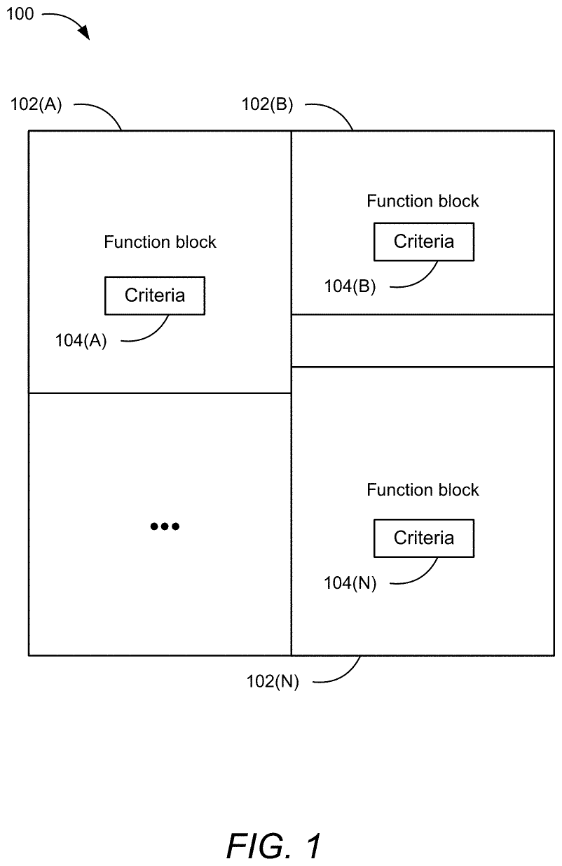

FIG. 1 illustrates an exemplary system-on-chip (SOC) 100, according to various aspects of the disclosure. The SOC 100 may include multiple (e.g., N, where N>0) function blocks, such as a function block 102(A), a function block 102(B), up to a function block 102(N). Each of the function blocks 102 may perform a specific function. For example, the function blocks 102 may include a microprocessor (e.g., with multiple cores) function, a graphics processing unit (GPU) function, a communications interface function (e.g., Wi-Fi, Bluetooth, and other communications), an input/output (I/O) function, a shared memory function (e.g., shared between function blocks on the SOC), a digital signal processing (DSP) function, another type of function, or any combination thereof

Each of the function blocks 102 may have associated criteria that identifies a resistance, a capacitance, a width, a depth, and the like for individual connections, such as vias, particular (e.g., critical) paths, and other connections on the SOC 100. A critical path is a circuit path such that a delay in a signal along the circuit path may determine (e.g., gate) the frequency of the entire function block. Reducing an RC delay of critical paths increases a frequency at which a function block can operate. The function block 102(A) may have associated criteria 104(A), the function block 102(B) may have associated criteria 104(B), and the function block 102(N) may have associated criteria 104(C). One or more metals may be selected for a second metal layer of the SOC 100 based on the criteria 104 associated with each of the corresponding function blocks 102. For example, a first metal may be used in the second metal layer of the function block 102(A) based on the criteria 104(A), a second metal may be used in the second metal layer for the function block 102(B) based on the criteria 104(B), and a third metal may be used in the second metal layer for the function block 102(N) based on the criteria 104(N). In some cases, the first metal, the second metal, and the third metal may be the same metal. In other cases, two of the metals may be the same while one of the metals may be different. In still other cases, all three of the metals may be different from each other.

Thus, an advantage of using a particular metal for the second metal layer of a particular function block is that criteria associated with the particular function block may be satisfied. For example, a function block that is infrequently used, such as a wake-up function block, may use a metal that has a relatively high resistance because speed, heat buildup, or the like may be infrequently encountered. As another example, a function block that is frequently used or performs a large number of operations, such as a GPU, may use a metal with a relatively low resistance to enable high speed data interchange for high performance, to reduce heat buildup, and the like.

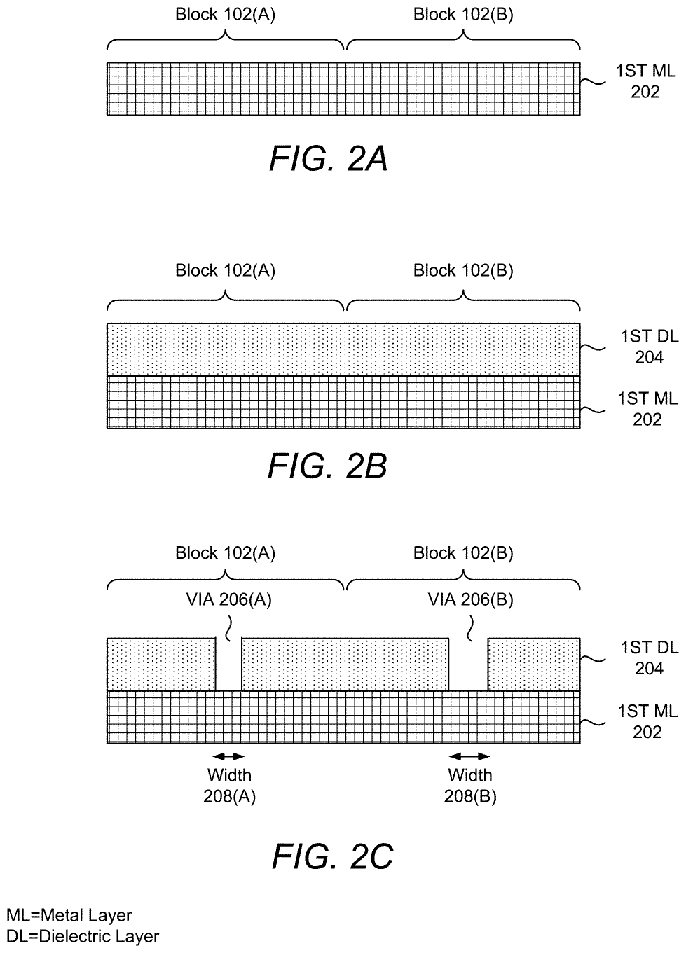

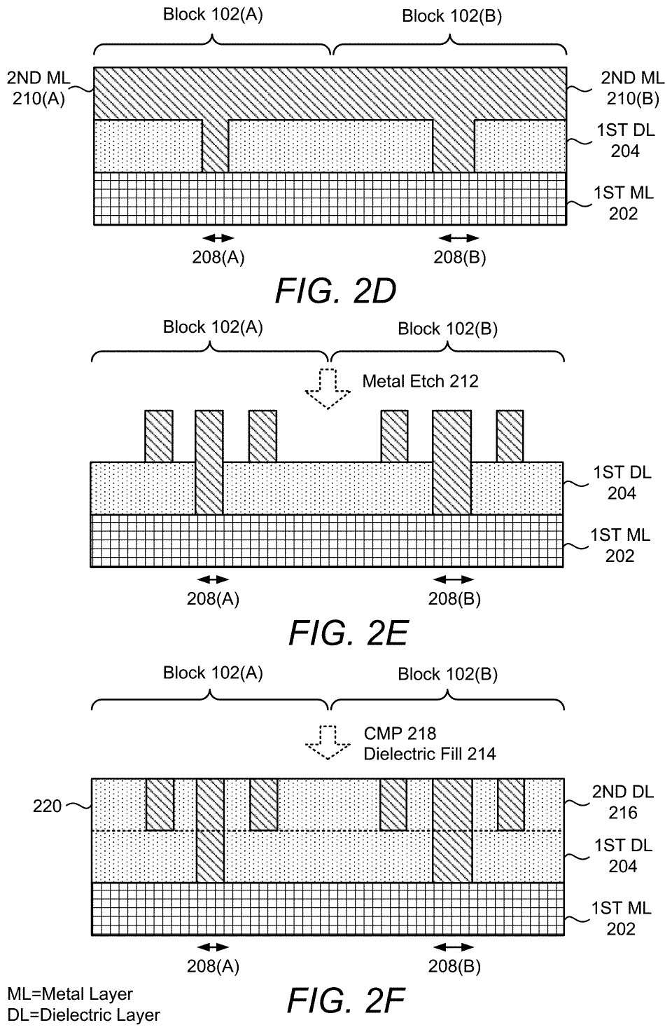

FIGS. 2A, 2B, 2C, 2D, 2E, and 2F illustrate stages of a first back end of line (BEOL) process that includes creating vias having different widths, according to aspects of the disclosure. FIGS. 2A, 2B, 2C, 2D, 2E, and 2F illustrate creating two function blocks 102(A) and 102(B) on a SOC. It should be understood that the two function blocks 102(A), 102(B) are shown for illustration purposes and that the systems and techniques described herein may be used to create more than two function blocks on a SOC

In FIG. 2A, a first metal layer (ML) 202 may be deposited. For example, the first metal layer 202 may include Cu, Co, Ru, W, Mo, Au, Ag, Al, Sn, another type of metal or any combination thereof. In some cases, the first layer may be a middle-of-the-line (MOL) conductor layer of W or Co. The MOL connects the separate transistor and interconnect pieces using a series of contact structures. In such cases, the second layer is the BEOL first metal layer 202. The first metal layer 202 can also be the first BEOL layer (and hence the second layer is then the second BEOL layer) using a metal such as, for example Cu or Co. For future nodes (e.g., that use a first BEOL metal layer pitch less than 22 nm), the BEOL first metal layer 202 conductor material may include, for example, Ru, Co, W or Mo.

In FIG. 2B, a first dielectric layer (DL) 204 may be deposited, e.g., on top of the first metal layer 202. The first dielectric layer 204 may be a low k dielectric, such as, for example, SiCOH or SiO2. In FIG. 2C, the first dielectric layer 204 may be etched to create at least one via, e.g., via 206(A), in function block 102(A) and at least one via, e.g., via 206(B), in function block 102(B). The via 206(A) may have a width 208(A) that is different from a width 208(A) of the via 206(B). For example, as illustrated in FIG. 2C, the width 208(B) may be greater than the width 208(A). Function block 102(B) may transfer large amounts of data or perform a large number of transactions and may use the width 208(B) of the via 206(B) to increase data transfer speeds, reduce heat buildup, or both.

In FIG. 2D, a second metal layer 210(A) may be deposited on the etched first dielectric layer 204 of the function block 102(A), including filling the via 206(A). A second metal layer 210(B) may be deposited on the etched first dielectric layer 204 of the function block 102(B), including filling the via 206(B). In various aspects discloses, metal layer 210(A) uses the same material as the metal layer 210(B). Each of the metal layers 210(A), 210(B) may include Cu, Co, Ru, W, Mo, Au, Ag, Al, Sn, another type of metal or any combination thereof, and preferably Ru or Co. For example, the first metal layer 202 may include Cu, the second metal layer 210(A) may include Co (or W), and the second metal layer 210(B) may include Co (or W). However, it will be appreciated that the various aspects are not limited to this configuration and other cases, the metal layer 210(A) may be different than the metal layer 210(B), e.g., depending on the criteria 104(A) associated with the function block 102(A) and the criteria 104(B) associated with the function block 102(B).

FIG. 2E illustrates a result of performing a metal etch 212 to the second metal layers 210(A), 210(B). The metal etch 212 may be performed using a plasma etch. For example, CF4/O2 plasma may be used for an Ru etch. Of course, the chemical selected to perform the metal etch 212 depends on the metal that is being etched. Usually, different metals need different chemicals FIG. 2F illustrates a result of performing a dielectric fill 214 to add a second dielectric layer 216 on top of the etched second metal layers 210(A), 210(B), and performing a chemical mechanical polishing (CMP) 218 to a top surface 220 of the second dielectric layer 216. As can be seen in FIG. 2F, the fill of the via 206(B) with the second metal layer 210(B) has a width 208(B) that is greater than the width 208(A) of the fill of the via 206(A) with the second metal layer 210(A). In this way, criteria associated with a particular function block, such as a wider critical path, a lower resistance connection (e.g. via), or the like can be achieved during the BEOL portion of the fabrication of the SOC.

The first dielectric layer 204 and the second dielectric layer 216 may include (a) one or more of a low K dielectric material (where K is a dielectric constant of the material), such as, for example, Nano-pourous Silica, Hydrogen-silsesquioxanes (HSQ), Polytetrafluoethylene (PTFE), and Silicon Oxyflouride (FSG) or (b) one or more of a high K dielectric material (e.g., 10<K<100), such as, for example, lead zirconate titanate (PZT), Tantalum Pentoxide (Ta₂O₅), Aluminum Oxide (Al₂O₃), Zirconium Dioxide (ZrO₂), and Hafnium Dioxide (HfO₂).

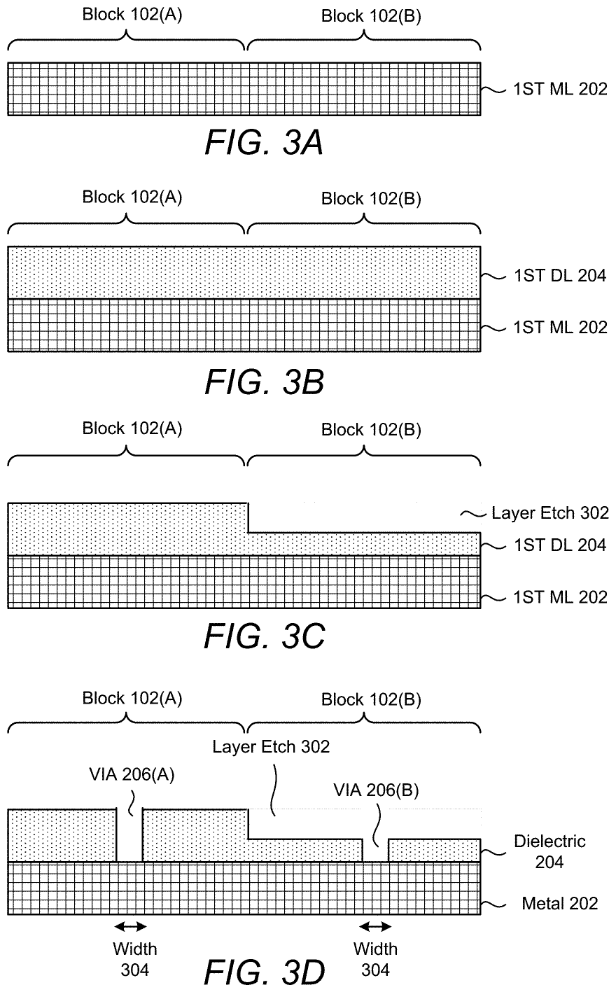

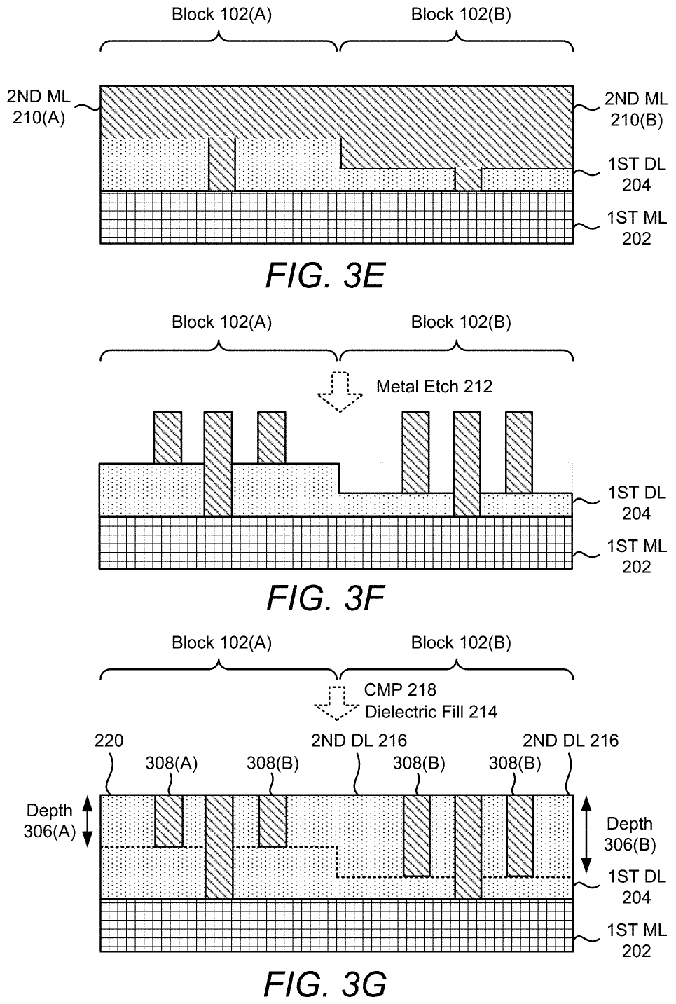

FIGS. 3A, 3B, 3C, 3D, 3E, 3F, and 3G illustrate stages of a second BEOL process that includes creating vias having different depths, according to aspects of the disclosure. FIGS. 3A, 3B, 3C, 3D, 3E, 3F, and 3G illustrate creating two function blocks 102(A) and 102(B) on a SOC. It should be understood that the two function blocks 102(A), 102(B) are shown for illustration purposes and that the systems and techniques described herein may be used to create more than two function blocks on a SOC.

In FIG. 3A, the first metal layer (ML) 202 may be deposited. For example, the first metal layer 202 may include Cu, Co, Ru, W, Mo, Au, Ag, Al, Sn, another type of metal or any combination thereof

In FIG. 3B, the first dielectric layer (DL) 204 may be deposited, e.g., on top of the first metal layer 202. In FIG. 3C, a layer etch 302 of the first dielectric layer 204 may be performed to remove a portion of the first dielectric layer 204. As illustrated in FIG. 3C, the layer etch 302 is performed to a particular function block, e.g., function block 102(B). FIG. 3D illustrates a result of performing the layer etch 302 to create at least one via, e.g., the via 206(A), in function block 102(A) and at least one via, e.g., the via 206(B), in function block 102(B). The via 206(A) may have a width 304 that is a same width as the via 206(B). Note that a depth of the via 206(A) is different than a depth of the via 206(A), due to the layer etch 302.

In FIG. 3E, a second metal layer 210(A) may be deposited on the etched first dielectric layer 204 of the function block 102(A), including filling the via 206(A). A second metal layer 210(B) may be deposited on the etched first dielectric layer 204 of the function block 102(B), including filling the via 206(B). In some cases, the metal layer 210(A) may be the same as the metal layer 210(B) while in other cases, the metal layer 210(A) may be different than the metal layer 210(B), e.g., depending on the criteria 104(A) associated with the function block 102(A) and the criteria 104(B) associated with the function block 102(B). Each of the metal layers 210(A), 210(B) may include Cu, Co, Ru, W, Mo, Au, Ag, Al, Sn, another type of metal or any combination thereof. For example, the first metal layer 202 may include Cu, the second metal layer 210(A) may include Co (or W), and the second metal layer 210(B) may include W (or Co).

FIG. 3F illustrates a result of performing the metal etch 212 to the second metal layers 210(A), 210(B). FIG. 3G illustrates a result of performing the dielectric fill 214 to add the dielectric layer 216 on top of the etched second metal layers 210(A), 210(B), and performing the CMP 218 to the top surface 220 of the second dielectric layer 216. As can be seen in FIG. 3G, connections 308(A) of the function block 102(A) have a depth 306(A) that is less than a depth 306(B) of the connections 308(B) of the function block 102(B). The deeper depth 306(B) results in lower resistance (and higher capacitance) for 308(B). This lower resistance is provided for circuits or function blocks that prefer lower R (and can tolerate a higher capacitance).

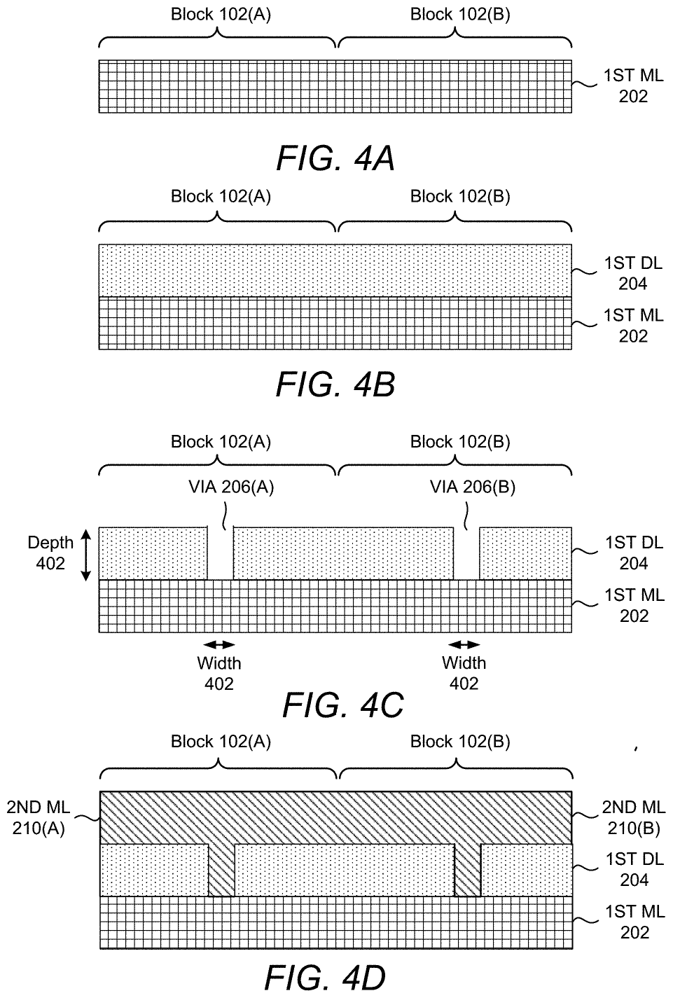

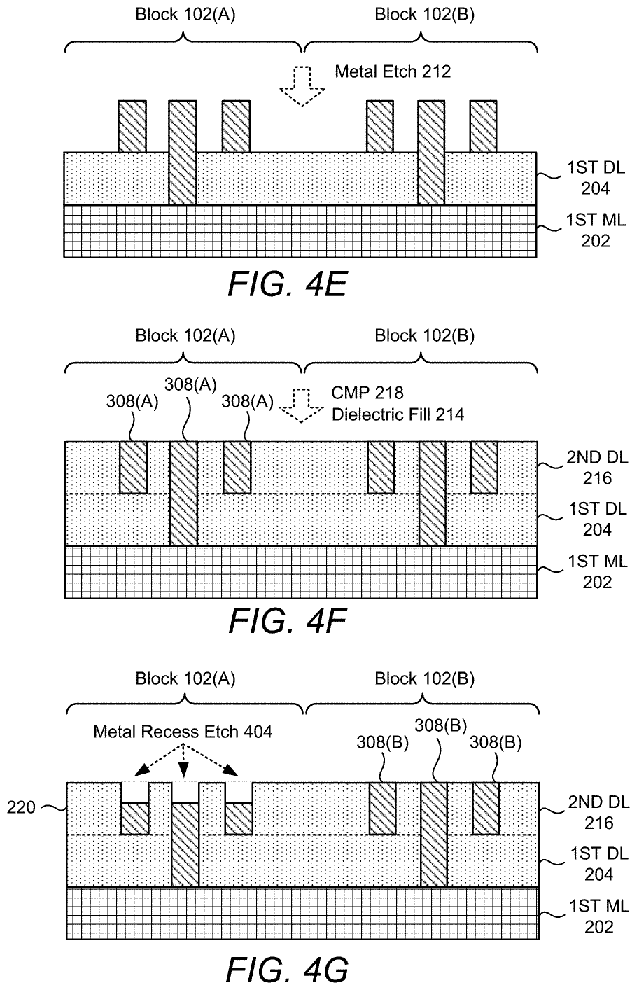

FIGS. 4A, 4B, 4C, 4D, 4E, 4F, and 4G illustrate stages of a third BEOL process that includes creating recessed vias, according to aspects of the disclosure. FIGS. 4A, 4B, 4C, 4D, 4E, 4F, and 4G illustrate creating two function blocks 102(A) and 102(B) on a SOC. It should be understood that the two function blocks 102(A), 102(B) are shown for illustration purposes and that the systems and techniques described herein may be used to create more than two function blocks on a SOC.

In FIG. 4A, the first metal layer (ML) 202 may be deposited. For example, the first metal layer 202 may include Cu, Co, Ru, W, Mo, Au, Ag, Al, Sn, another type of metal or any combination thereof

In FIG. 4B, the first dielectric layer (DL) 204 may be deposited, e.g., on top of the first metal layer 202. In FIG. 4C, the first dielectric layer 204 may be etched to create at least one via, e.g., via 206(A), in function block 102(A) and at least one via, e.g., via 206(B), in function block 102(B). The via 206(A) may have a width 402 that is the same width as the via 206(B).

In FIG. 4D, the second metal layer 210(A) may be deposited on the etched first dielectric layer 204 of the function block 102(A), including filling the via 206(A). The second metal layer 210(B) may be deposited on the etched first dielectric layer 204 of the function block 102(B), including filling the via 206(B). In some cases, the metal layer 210(A) may be the same as the metal layer 210(B) while in other cases, the metal layer 210(A) may be different than the metal layer 210(B), e.g., depending on the criteria 104(A) associated with the function block 102(A) and the criteria 104(B) associated with the function block 102(B). Each of the metal layers 210(A), 210(B) may include Cu, Co, Ru, W, Mo, Au, Ag, Al, Sn, another type of metal or any combination thereof. For example, the first metal layer 202 may include Cu, the second metal layer 210(A) may include Co (or W), and the second metal layer 210(B) may include W (or Co).

FIG. 4E illustrates a result of performing the metal etch 212 to the second metal layers 210(A), 210(B) of FIG. 4D. FIG. 4F illustrates a result of performing a dielectric fill 214 to add the second dielectric layer 216 on top of the etched second metal layers 210(A), 210(B), and performing the CMP 218 to the top surface 220 of the second dielectric layer 216.

FIG. 4G illustrates a result of performing a metal recess etch on a particular function block, e.g., function block 102(A), to recess the connections 308(A) of the particular function block below the top surface 220 of the second dielectric layer 216. The connections 308(B) of the other function blocks, e.g., the function block 102(B), remain at a same level as the top surface 220. Recessing the metal lines using the metal recess etch 404 results in lower metal capacitance (and higher metal R) in function block 102(A). The metal recess etch 404 benefits the function block 102(A) when the function block prefers lower metal capacitance (and can tolerate higher metal R).

The BEOL processes described above are not intended to be mutually exclusive but rather to illustrate how the systems and techniques may be used to provide at least two different function blocks on the same SOC. The different figures may be combined in different ways, as illustrated in the flow diagrams below, to customize each function block on a SOC.

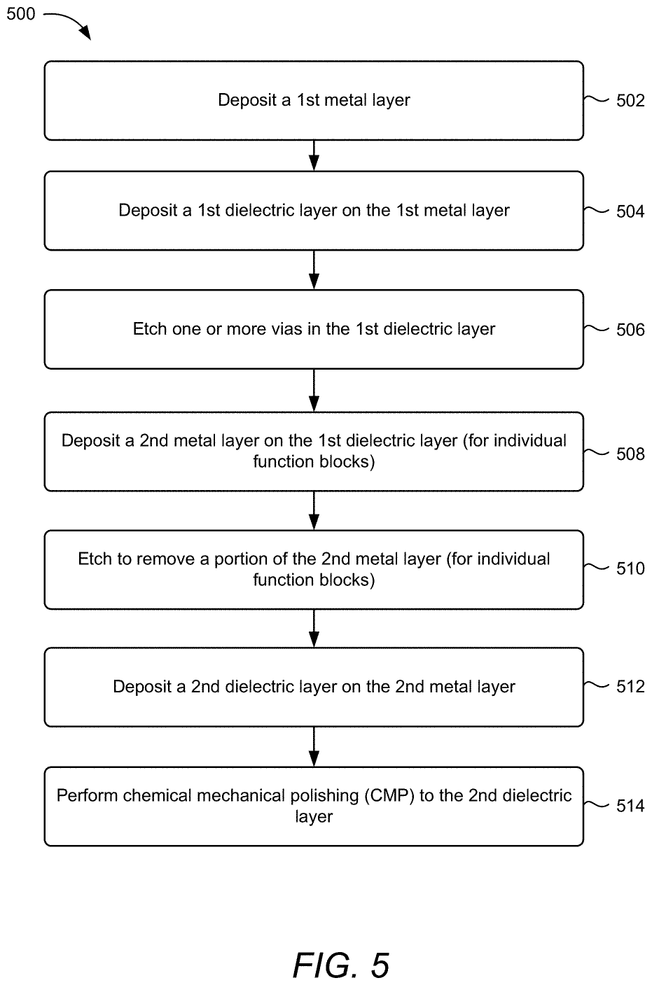

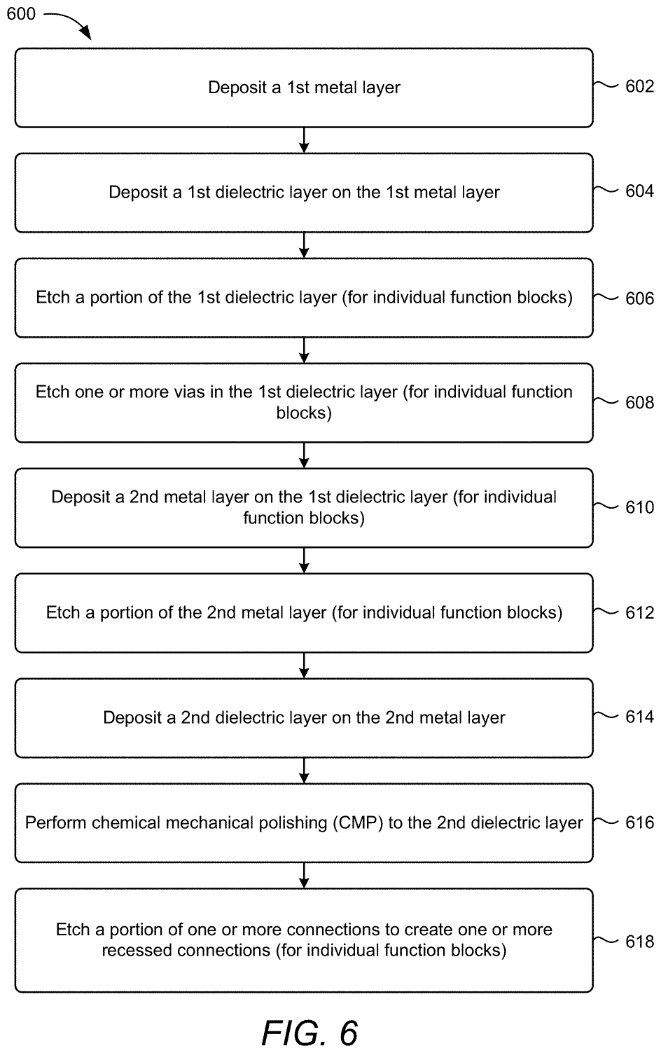

In the flow diagrams of FIGS. 5 and 6, each block represents one or more operations that can be implemented in hardware, software, or a combination thereof. In the context of software, the blocks represent computer-executable instructions that, when executed by one or more processors, cause the processors to perform the recited operations. Generally, computer-executable instructions include routines, programs, objects, modules, components, data structures, and the like that perform particular functions or implement particular abstract data types. The order in which the blocks are described is not intended to be construed as a limitation, and any number of the described operations can be combined in any order and/or in parallel to implement the processes. For discussion purposes, the processes 500 and 600 are described with reference to FIGS. 1, 2A-2F, 3A-3G, and 4A-4G, as described above, although other models, frameworks, systems and environments may be used to implement these processes.

FIG. 5 illustrates an example process 500 that includes depositing a second metal layer on a first dielectric layer, according to aspects of the disclosure. The process 500 may be performed during a manufacturer of a SOC, such as during BEOL.

At 502, the process may deposit a first metal layer (e.g., on a wafer). For example, in FIGS. 2A, 3A, and 4A, the process may deposit the first metal layer 202.

At 504, the process may deposit a first dielectric layer on top of the first metal layer. For example, in FIGS. 2B, 3B, and 4B, the process may deposit the first dielectric layer 204.

At 506, the process may etch one or more vias in the first dielectric layer. For example, in FIGS. 2C, 3D, and 4C, the process may etch the at least one via 206(A) in function block 102(A) and may etch the at least one via 206(B) in function block 102(B).

At 508, the process may deposit, for individual function blocks, a second metal layer on top of the first dielectric layer. For example, in FIGS. 2D, 3E, and 4D, the process may deposit the 2nd metal layer 210(A) for the function block 102(A) and the 2nd metal layer 210(B) for the function block 102(B).

At 510, the process may, for individual function blocks, etch to remove a portion of the second metal layer. For example, in FIGS. 2E, 3F, and 4E, the process may perform the metal etch 212 to remove a portion of the second metal layers 210(A), 210(B).

At 512, the process may deposit a second dielectric layer on top of the second metal layer. For example, in FIGS. 2F, 3G, and 4F, the process may perform the dielectric fill 214 to add the second dielectric layer 216.

At 514, the process may perform chemical mechanical polishing (CMP) to the second dielectric layer. For example, in FIGS. 2F, 3G, and 4F, the process may perform the CMP 218 to the top surface 220 of the second dielectric layer 216.

Thus, different metals may be used in a second metal layer during BEOL based on the particular criteria associated with a particular function block. For example, a metal with a relatively low resistance may be used as the second metal layer for a function block that sends large amounts of data or that can overheat if there is too much resistance in internal connections. A metal with a relatively high resistance may be used as the second metal layer for a function block that is infrequently used, such as a wake-up function.

FIG. 6 illustrates an example process 600 that includes creating one or more recessed etches, according to aspects of the disclosure. The process 600 may be performed during a manufacturer of a SOC, such as during BEOL.

At 602, the process may deposit a first metal layer (e.g., on a wafer). For example, in FIGS. 2A, 3A, and 4A, the process may deposit the first metal layer 202.

At 604, the process may deposit a first dielectric layer on top of the first metal layer. For example, in FIGS. 2B, 3B, and 4B, the process may deposit the first dielectric layer 204.

At 606, in some cases, the process may remove via etching, for individual function blocks, a portion of the first dielectric layer. For example, in FIG. 3C, the process may perform the layer etch 302 to remove a portion of the first dielectric layer 204 of the function block 102(B) (e.g., without affecting the first dielectric layer 204 of the function block 102(A)).

At 608, the process may, for individual function blocks, etch one or more vias in the first dielectric layer. For example, in FIGS. 2C, 3D, and 4C, the process may etch the at least one via 206(A) in function block 102(A) and may etch the at least one via 206(B) in function block 102(B).

At 610, the process may deposit, for individual function blocks, a second metal layer on top of the first dielectric layer. For example, in FIGS. 2D, 3E, and 4D, the process may deposit the 2nd metal layer 210(A) for the function block 102(A) and the 2nd metal layer 210(B) for the function block 102(B).

At 612, the process may, for individual function blocks, etch to remove a portion of the second metal layer. For example, in FIGS. 2E, 3F, and 4E, the process may perform the metal etch 212 to remove a portion of the second metal layers 210(A), 210(B).

At 614, the process may deposit a second dielectric layer on top of the second metal layer. For example, in FIGS. 2F, 3G, and 4F, the process may perform the dielectric fill 214 to add the second dielectric layer 216.

At 616, the process may perform chemical mechanical polishing (CMP) to the second dielectric layer. For example, in FIGS. 2F, 3G, and 4F, the process may perform the CMP 218 to the top surface 220 of the second dielectric layer 216.

At 618, in some cases, the process may remove, for individual function blocks, via etching, a portion of one or more of the vias to create one or more recessed connections. For example, in FIG. 4G, the metal recess etch 404 may be used to recess connectors below the top surface 220.

Thus, an advantage provided by the BEOL processes described herein is that function blocks can be customized to satisfy different criteria associated with each function block. For example, a particular function block may use a different metal for the second metal layer than another function block, the particular function block may have a via that is wider than another function block, the particular function block may have connectors that have a greater depth than another function block, the particular function block may have connectors, a via, or both that are recessed compared to another function block, or any combination thereof. In this way, different resistance and capacitance criteria associated with each function block may be satisfied, enabling faster throughput (e.g., due to lower resistance), less heat buildup, and the like.

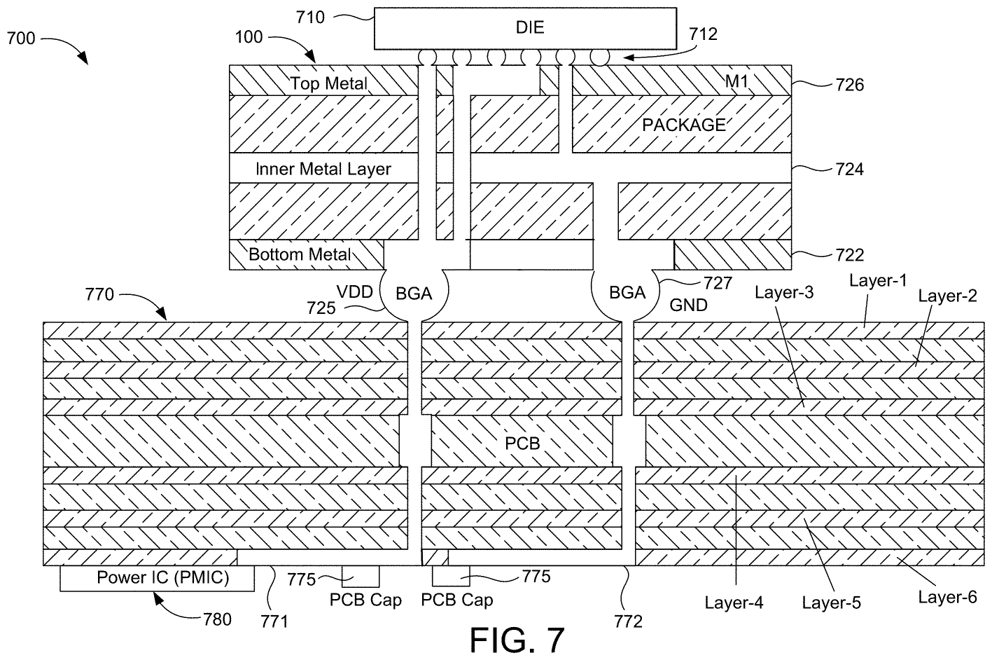

FIG. 7 illustrates components of an integrated device 700 according to one or more aspects of the disclosure. Regardless of the various BEOL techniques discussed above, it will be appreciated that the SOC 100 may be configured to couple to a PCB 790. The PCB 790 is also coupled to a power supply 780 (e.g., a power management integrated circuit (PMIC)), which allows the package 720 and the SOC 100 to be electrically coupled to the PMIC 780. Specifically, one or more power supply (VDD) lines 791 and one or more ground (GND) lines 792 may be coupled to the PMIC 780 to distribute power to the PCB 790, package 720 via VDD BGA pin 725 and GND BGA pin 727 and to the die 710 via die bumps 712 (which may be plated UBMs of various sizes and pitches, coupled to the top metal layer/M1 layer 726 of package 720, as discussed above). The VDD line 791 and GND line 792 each may be formed from traces, shapes or patterns in one or more metal layers of the PCB 790 (e.g., layers 1-6) coupled by one or more vias through insulating layers separating the metal layers 1-6 in the PCB 790. The PCB 790 may have one or more PCB capacitors (PCB cap) 795 that can be used to condition the power supply signals, as is known to those skilled in the art. Additional connections and devices may be coupled to and/or pass through the PCB 790 to the package 720 via one or more additional BGA pins (not illustrated) on the package 720. It will be appreciated that the illustrated configuration and descriptions are provided merely to aid in the explanation of the various aspects disclosed herein. For example, the PCB 490 may have more or less metal and insulating layers, there may be multiple lines providing power to the various components, etc. Accordingly, the forgoing illustrative examples and associated figures should not be construed to limit the various aspects disclosed and claimed herein

In accordance with the various aspects disclosed herein, at least one aspect includes a SOC with multiple function blocks. Individual function blocks of the SOC may include connections with particular R characteristics, particular C characteristics, or both. Among the various technical advantages, the various aspects disclosed provide, in at least some aspects, customizing the resistance (R), capacitance (C), or both of different connections (including vias) of individual function blocks located on a same SOC. In this way, function blocks performing a large number of operations, transferring large amounts of data, or the like benefit from paths that provide lower resistance based in part on the metal use in the 2nd metal layer, the width of the connection, the depth of the connection, and the like to increase throughput, reduce heat buildup, or the like. Other technical advantages will be recognized from various aspects disclosed herein and these technical advantages are merely provided as examples and should not be construed to limit any of the various aspects disclosed herein.

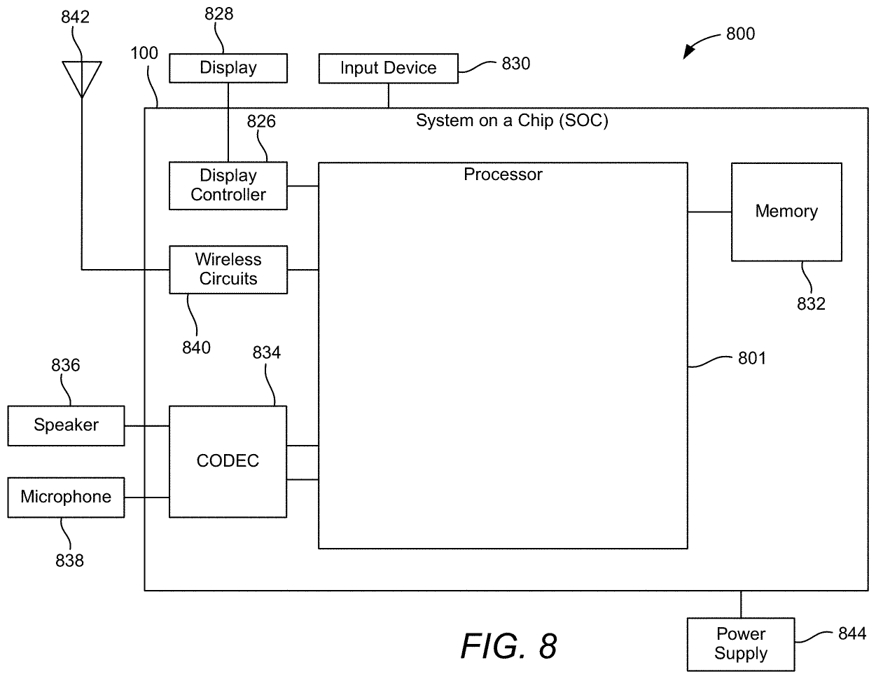

FIG. 8 illustrates an exemplary mobile device in accordance with some examples of the disclosure. Referring now to FIG. 8, a block diagram of a mobile device that is configured according to exemplary aspects is depicted and generally designated mobile device 800. In some aspects, mobile device 800 may be configured as a wireless communication device. As shown, mobile device 800 includes processor 801. Processor 801 may be communicatively coupled to memory 832 over a link, which may be a die-to-die or chip-to-chip link. Mobile device 800 also includes display 828 and display controller 826, with display controller 826 coupled to processor 801 and to display 828.

In some aspects, FIG. 8 may include coder/decoder (CODEC) 834 (e.g., an audio and/or voice CODEC) coupled to processor 801; speaker 836 and microphone 838 coupled to CODEC 834; and wireless circuits 840 (which may include a modem, RF circuitry, filters, etc., which may be implemented using one or more flip-chip devices, as disclosed herein) coupled to wireless antenna 842 and to processor 801.

In a particular aspect, where one or more of the above-mentioned blocks are present, processor 801, display controller 826, memory 832, CODEC 834, and wireless circuits 840 can be included in the system-on-chip (SOC) 100 which may be implemented in whole or part using the BEOL techniques disclosed herein. Input device 830 (e.g., physical or virtual keyboard), power supply 844 (e.g., battery), display 828, input device 830, speaker 836, microphone 838, wireless antenna 842, and power supply 844 may be external to SOC 100 and may be coupled to a component of SOC 100, such as an interface or a controller.

It should be noted that although FIG. 8 depicts a mobile device 800, processor 801 and memory 832 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

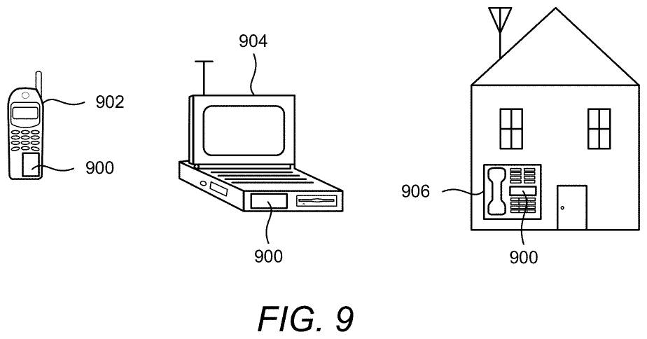

FIG. 9 illustrates various electronic devices that may be integrated with any of the aforementioned integrated device or semiconductor device accordance with various examples of the disclosure. For example, a mobile phone device 902, a laptop computer device 904, and a fixed location terminal device 906 may each be considered generally user equipment (UE) and may include a flip-chip device 900 as described herein. The flip-chip device 900 may be, for example, any of the integrated circuits, dies, integrated devices, integrated device packages, integrated circuit devices, device packages, integrated circuit (IC) packages, package-on-package devices described herein. The devices 902, 904, 906 illustrated in FIG. 9 are merely exemplary. Other electronic devices may also feature the flip-chip device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof

It can be noted that, although particular frequencies, integrated circuits (ICs), hardware, and other features are described in the aspects herein, alternative aspects may vary. That is, alternative aspects may utilize additional or alternative frequencies (e.g., other the 60 GHz and/or 28 GHz frequency bands), antenna elements (e.g., having different size/shape of antenna element arrays), scanning periods (including both static and dynamic scanning periods), electronic devices (e.g., WLAN APs, cellular base stations, smart speakers, IoT devices, mobile phones, tablets, personal computer (PC), etc.), and/or other features. A person of ordinary skill in the art will appreciate such variations.

It should be understood that any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be employed there or that the first element must precede the second element in some manner. Also, unless stated otherwise a set of elements may comprise one or more elements. In addition, terminology of the form “at least one of A, B, or C” or “one or more of A, B, or C” or “at least one of the group consisting of A, B, and C” used in the description or the claims means “A or B or C or any combination of these elements.” For example, this terminology may include A, or B, or C, or A and B, or A and C, or A and B and C, or 2A, or 2B, or 2C, and so on.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause. Implementation examples are described in the following numbered clauses:

Clause 1. An apparatus comprising a system on a chip (SOC) comprising: a first metal layer; a first dielectric layer located on top of the first metal layer; a first via located in the first dielectric layer used in a first function block of a plurality of function blocks, wherein the plurality of function blocks are co-located on the SOC; a second via located in the first dielectric layer used in a second function block of the plurality of function blocks; a second metal layer located on the first dielectric layer, wherein the second metal layer comprises: a first set of connections used in the first function block; and a second set of connections used in the second function block, wherein the first set of connections is different from the second set of connections; and a second dielectric layer located on the first dielectric layer.

Clause 2. The apparatus of clause 1, wherein a first depth of the first set of connections is different than a second depth of the second set of connections.

Clause 3. The apparatus of clause 2, wherein a first thickness of the first dielectric layer adjacent the first set of connections is different than a second thickness of the first dielectric layer adjacent the second set of connections.

Clause 4. The apparatus of clause 3, wherein the first thickness is greater than the second thickness and the first depth is less than the second depth.

Clause 5. The apparatus of clause 1, wherein the first set of connections are recessed below a top surface of the second dielectric layer and the second set of connections are flush with the top surface of the second dielectric layer.

Clause 6. The apparatus of clause 1, wherein the first via has a first width and the second via has a second width that is different than the first width.

Clause 7. The apparatus of any of clauses 4 to 6, wherein the first set of connections each has a first width and the second set of connections each has the first width.

Clause 8. The apparatus of any of clauses 1 to 6, wherein the first set of connections each has a first width and the second set of connections each has a second width and wherein the first width is different than the second width.

Clause 9. The apparatus of any of clauses 1 to 8, wherein the second metal layer comprises at least one of Copper (Cu), Cobalt (Co), Ruthenium (Ru), Tungsten/Wolfram (W), Molybdenum (Mo), Gold (Au), Silver (Ag), Aluminum (Al), or Tin (Sn).

Clause 10. The apparatus of any of clauses 1 to 9, wherein the first metal layer comprises at least one of: Copper (Cu), Cobalt (Co), Ruthenium (Ru), Tungsten/Wolfram (W), Molybdenum (Mo), Gold (Au), Silver (Ag), Aluminum (Al), or Tin (Sn).

Clause 11. The apparatus of any of clauses 1 to 10, wherein the first via and the first set of connections and the second via and the second set of connections are formed of a same material.

Clause 12. The apparatus of any of clauses 1 to 10, wherein the first via and the first set of connections are formed of a first material and the second via and the second set of connections are formed of a second material different from the first material.

Clause 13. The apparatus of any of clauses 1 to 12, wherein a first pitch of the first set of connections is different than a second pitch of the second set of connections.

Clause 14. The apparatus of any of clauses 1 to 13, wherein a first resistance of the first set of connections is different than a second resistance of the second set of connections.

Clause 15. The apparatus of any of clauses 1 to 14, wherein a first capacitance of the first set of connections is different than a second capacitance of the second set of connections.

Clause 16. The apparatus of any of clauses 1 to 15, wherein the plurality of function blocks comprise at least two of: a microprocessor, a graphics processing unit (GPU), a communications interface, an input/output (I/O) interface, a shared memory, and a digital signal processor (DSP).

Clause 17. The apparatus of any of clauses 1 to 16, wherein the first dielectric layer and the second dielectric layer each comprises at least one of: Nano-pourous Silica, Hydrogen-silsesquioxanes (HSQ), Polytetrafluoethylene (PTFE), Silicon Oxyflouride (FSG), Lead Zirconate Titanate (PZT), Tantalum Pentoxide (Ta2O5), Aluminum Oxide (Al2O3), Zirconium Dioxide (ZrO2), or Hafnium Dioxide (HfO2).

Clause 18. The apparatus of any of clauses 1 to 17, wherein the apparatus is incorporated into a device selected from the group consisting of: a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a base station, a laptop computer, a server, and a device in an automotive vehicle.

Clause 19. A method of fabricating a system on a chip (SOC) comprising: depositing a first metal layer on a substrate; depositing a first dielectric layer on the first metal layer; etching a first via in the first dielectric layer, the first via used in a first function block of a plurality of function blocks, wherein the plurality of function blocks are co-located on the SOC; etching a second via located in the first dielectric layer used in a second function block of the plurality of function blocks; depositing, a second metal layer on top of the first dielectric layer, wherein the second metal layer comprises: a first set of connections used in the first function block; and a second set of connections used in the second function block, wherein the first set of connections is different from the second set of connections; removing a portion of the second metal layer; and depositing a second dielectric layer on the first dielectric layer.

Clause 20. The method of clause 19, further comprising: performing a chemical mechanical polish (CMP) of the second dielectric layer.

Clause 21. The method of any of clauses 19 to 20, wherein: a first depth of the first set of connections is different than a second depth of the second set of connections.

Clause 22. The method of clause 21, wherein: a first thickness of the first dielectric layer adjacent the first set of connections is different than a second thickness of the first dielectric layer adjacent the second set of connections.

Clause 23. The method of clause 22, wherein: the first thickness is greater than the second thickness and the first depth is less than the second depth.

Clause 24. The method of any of clauses 19 to 20, wherein: the first set of connections are recessed below a top surface of the second dielectric layer, and the second set of connections are flush with the top surface of the second dielectric layer.

Clause 25. The method of any of clauses 19 to 20, wherein: the first via has a first width and the second via has a second width that is different than the first width.

Clause 26. The method of any of clauses 19 to 25, wherein the second metal layer comprises at least one of Copper (Cu), Cobalt (Co), Ruthenium (Ru), Tungsten/Wolfram (W), Molybdenum (Mo), Gold (Au), Silver (Ag), Aluminum (Al), or Tin (Sn).

Clause 27. The method of any of clauses 19 to 26, wherein the first metal layer comprises at least one of Copper (Cu), Cobalt (Co), Ruthenium (Ru), Tungsten/Wolfram (W), Molybdenum (Mo), Gold (Au), Silver (Ag), Aluminum (Al), or Tin (Sn).

Clause 28. The method of any of clauses 19 to 27, wherein the first via and the first set of connections and the second via and the second set of connections are formed of a same material.

Clause 29. The method of any of clauses 19 to 27, wherein the first via and the first set of connections are formed of a first material and the second via and the second set of connections are formed of a second material different from the first material.

Clause 30. The method of any of clauses 19 to 29, wherein a first pitch of the first set of connections is different than a second pitch of the second set of connections.

Clause 31. The method of any of clauses 19 to 30, wherein a first resistance of the first set of connections is different than a second resistance of the second set of connections.

Clause 32. The method of any of clauses 19 to 31, wherein a first capacitance of the first set of connections is different than a second capacitance of the second set of connections.

Clause 33. The method of any of clauses 19 to 32, wherein the plurality of function blocks comprise at least two of: a microprocessor, a graphics processing unit (GPU), a communications interface, an input/output (I/O) interface, a shared memory, and a digital signal processor (DSP).

Clause 34. The method of any of clauses 19 to 33, wherein the first dielectric layer and the second dielectric layer each comprises at least one of: Nano-pourous Silica, Hydrogen-silsesquioxanes (HSQ), Polytetrafluoethylene (PTFE), Silicon Oxyflouride (FSG), Lead Zirconate Titanate (PZT), Tantalum Pentoxide (Ta2O5), Aluminum Oxide (Al2O3), Zirconium Dioxide (ZrO2), or Hafnium Dioxide (HfO2).

Clause 35. The method of any of clauses 19 to 34, wherein the SOC is incorporated into an apparatus selected from the group consisting of: a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a base station, a laptop computer, a server, and a device in an automotive vehicle.

In view of the descriptions and explanations above, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Accordingly, it will be appreciated, for example, that an apparatus or any component of an apparatus may be configured to (or made operable to or adapted to) provide functionality as taught herein. This may be achieved, for example: by manufacturing (e.g., fabricating) the apparatus or component so that it will provide the functionality; by programming the apparatus or component so that it will provide the functionality; or through the use of some other suitable implementation technique. As one example, an integrated circuit may be fabricated to provide the requisite functionality. As another example, an integrated circuit may be fabricated to support the requisite functionality and then configured (e.g., via programming) to provide the requisite functionality. As yet another example, a processor circuit may execute code to provide the requisite functionality.

Moreover, the methods, sequences, and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor (e.g., cache memory).

While the foregoing disclosure shows various illustrative aspects, it should be noted that various changes and modifications may be made to the illustrated examples without departing from the scope defined by the appended claims. The present disclosure is not intended to be limited to the specifically illustrated examples alone. For example, unless otherwise noted, the functions, steps, and/or actions of the method claims in accordance with the aspects of the disclosure described herein need not be performed in any particular order. Furthermore, although certain aspects may be described or claimed in the singular, the plural is contemplated unless limitation to the singular is explicitly stated.

What is claimed is:

1. An apparatus comprising a system on a chip (SOC) comprising:
a first metal layer;
a first dielectric layer located on top of the first metal layer;
a first via located in the first dielectric layer used in a first function block of a plurality of function blocks, wherein the plurality of function blocks are co-located on the SOC;
a second via located in the first dielectric layer used in a second function block of the plurality of function blocks;
a second metal layer located on the first dielectric layer, wherein the second metal layer comprises:
a first set of connections used in the first function block; and
a second set of connections used in the second function block, wherein the first set of connections is different from the second set of connections; and
a second dielectric layer located on the first dielectric layer.

2. The apparatus of claim 1, wherein a first depth of the first set of connections is different than a second depth of the second set of connections.

3. The apparatus of claim 2, wherein a first thickness of the first dielectric layer adjacent the first set of connections is different than a second thickness of the first dielectric layer adjacent the second set of connections.

4. The apparatus of claim 3, wherein the first thickness is greater than the second thickness and the first depth is less than the second depth.

5. The apparatus of claim 1, wherein the first set of connections are recessed below a top surface of the second dielectric layer and the second set of connections are flush with the top surface of the second dielectric layer.

6. The apparatus of claim 1, wherein the first via has a first width and the second via has a second width that is different than the first width.

7. The apparatus of claim 4, wherein the first set of connections each has a first width and the second set of connections each has the first width.

8. The apparatus of claim 1, wherein the first set of connections each has a first width and the second set of connections each has a second width and wherein the first width is different than the second width.

9. The apparatus of claim 1, wherein the second metal layer comprises at least one of Copper (Cu), Cobalt (Co), Ruthenium (Ru), Tungsten/Wolfram (W), Molybdenum (Mo), Gold (Au), Silver (Ag), Aluminum (Al), or Tin (Sn).

10. The apparatus of claim 1, wherein the first metal layer comprises at least one of: Copper (Cu), Cobalt (Co), Ruthenium (Ru), Tungsten/Wolfram (W), Molybdenum (Mo), Gold (Au), Silver (Ag), Aluminum (Al), or Tin (Sn).

11. The apparatus of claim 1, wherein the first via and the first set of connections and the second via and the second set of connections are formed of a same material.

12. The apparatus of claim 1, wherein the first via and the first set of connections are formed of a first material and the second via and the second set of connections are formed of a second material different from the first material.

13. The apparatus of claim 1, wherein a first pitch of the first set of connections is different than a second pitch of the second set of connections.

14. The apparatus of claim 1, wherein a first resistance of the first set of connections is different than a second resistance of the second set of connections.

15. The apparatus of claim 1, wherein a first capacitance of the first set of connections is different than a second capacitance of the second set of connections.

16. The apparatus of claim 1, wherein the plurality of function blocks comprise at least two of:
a microprocessor,
a graphics processing unit (GPU),
a communications interface,
an input/output (I/O) interface,
a shared memory, and
a digital signal processor (DSP).

17. The apparatus of claim 1, wherein the first dielectric layer and the second dielectric layer each comprises at least one of:
Nano-pourous Silica, Hydrogen-silsesquioxanes (HSQ), Polytetrafluoethylene (PTFE), Silicon Oxyflouride (FSG), Lead Zirconate Titanate (PZT), Tantalum Pentoxide (Ta₂O₅), Aluminum Oxide (Al₂O₃), Zirconium Dioxide (ZrO₂), or Hafnium Dioxide (HfO₂).

18. The apparatus of claim 1, wherein the apparatus is incorporated into a device selected from the group consisting of: a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a base station, a laptop computer, a server, and a device in an automotive vehicle.

19. A method of fabricating a system on a chip (SOC) comprising:
depositing a first metal layer on a substrate;
depositing a first dielectric layer on the first metal layer;
etching a first via in the first dielectric layer, the first via used in a first function block of a plurality of function blocks, wherein the plurality of function blocks are co-located on the SOC;
etching a second via located in the first dielectric layer used in a second function block of the plurality of function blocks;
depositing, a second metal layer on top of the first dielectric layer, wherein the second metal layer comprises:
a first set of connections used in the first function block; and
a second set of connections used in the second function block, wherein the first set of connections is different from the second set of connections;
removing a portion of the second metal layer; and
depositing a second dielectric layer on the first dielectric layer.

20. The method of claim 19, further comprising:
performing a chemical mechanical polish (CMP) of the second dielectric layer.

21. The method of claim 19, wherein:
a first depth of the first set of connections is different than a second depth of the second set of connections.

22. The method of claim 21, wherein:
a first thickness of the first dielectric layer adjacent the first set of connections is different than a second thickness of the first dielectric layer adjacent the second set of connections.

23. The method of claim 22, wherein:
the first thickness is greater than the second thickness and the first depth is less than the second depth.

24. The method of claim 19, wherein:
the first set of connections are recessed below a top surface of the second dielectric layer, and
the second set of connections are flush with the top surface of the second dielectric layer.

25. The method of claim 19, wherein:
the first via has a first width and the second via has a second width that is different than the first width.

26. The method of claim 19, wherein the second metal layer comprises at least one of Copper (Cu), Cobalt (Co), Ruthenium (Ru), Tungsten/Wolfram (W), Molybdenum (Mo), Gold (Au), Silver (Ag), Aluminum (Al), or Tin (Sn).

27. The method of claim 19, wherein the first metal layer comprises at least one of Copper (Cu), Cobalt (Co), Ruthenium (Ru), Tungsten/Wolfram (W), Molybdenum (Mo), Gold (Au), Silver (Ag), Aluminum (Al), or Tin (Sn).

28. The method of claim 19, wherein the first via and the first set of connections and the second via and the second set of connections are formed of a same material.

29. The method of claim 19, wherein the first via and the first set of connections are formed of a first material and the second via and the second set of connections are formed of a second material different from the first material.

30. The method of claim 19, wherein a first pitch of the first set of connections is different than a second pitch of the second set of connections.

31. The method of claim 19, wherein a first resistance of the first set of connections is different than a second resistance of the second set of connections.

32. The method of claim 19, wherein a first capacitance of the first set of connections is different than a second capacitance of the second set of connections.

33. The method of claim 19, wherein the plurality of function blocks comprise at least two of:
a microprocessor,
a graphics processing unit (GPU),
a communications interface,
an input/output (I/O) interface,
a shared memory, and
a digital signal processor (DSP).

34. The method of claim 19, wherein the first dielectric layer and the second dielectric layer each comprises at least one of:
Nano-pourous Silica, Hydrogen-silsesquioxanes (HSQ), Polytetrafluoethylene (PTFE), Silicon Oxyflouride (FSG), Lead Zirconate Titanate (PZT), Tantalum Pentoxide (Ta₂O₅), Aluminum Oxide (Al₂O₃), Zirconium Dioxide (ZrO₂), or Hafnium Dioxide (HfO₂).

35. The method of claim 19, wherein the SOC is incorporated into an apparatus selected from the group consisting of: a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a base station, a laptop computer, a server, and a device in an automotive vehicle.
